(19) United States
(12) Patent Application Publication
(10) Pub. No.: US 2014/0151317 A1
(43) Pub. Date: Jun. 5, 2014

(54) ENCLOSURE ASSEMBLY FOR RECEIVING DATA STORAGE DEVICE

(71) Applicant: HON HAI PRECISION INDUSTRY CO., LTD., New Taipei (TW)

(72) Inventor: CHING-YI SHIH, New Taipei (TW)

(21) Appl. No.: 13/943,750

(22) Filed: Jul. 16, 2013

(30) Foreign Application Priority Data
Dec. 4, 2012 (TW) 101145367

(51) Int. Cl. H05K 5/00

(52) U.S. Cl. CPC H05K 5/0021
USPC 211/126.3; 211/126.2

(57) ABSTRACT

A enclosure assembly includes a plurality of trays. Each of the plurality of trays includes a first sidewall and a second sidewall opposite to the first sidewall. A plurality of engaging posts are located on the first sidewall, and a plurality of engaging holes is defined in the second sidewall. Each of the four engaging posts in one of the trays is engaged in each of the plurality of engaging holes in another one of the trays, so that two adjacent trays can be engaged to each other without screws or bolts, and it is very convenient for an end user to expand the capacity of the enclosure assembly.

### BACKGROUND

1. Technical Field

The present disclosure relates to enclosure assemblies, and especially to an enclosure assembly for receiving data storage devices.

2. Description of Related Art

Various data storage devices are installed in computers for communication and handling of data. Such devices include, for example, hard disk drives, floppy disk drives, and CD-ROM drives. A conventional data storage device is attached to a bracket with bolts, and then the bracket is secured to the computer enclosure with screws or bolts, which is very inconvenient when assembling or disassembling the bracket from the computer enclosure to add another data storage device because the bracket has a limitation capacity that cannot satisfy end user requirement.

### BRIEF DESCRIPTION OF THE DRAWINGS

Many aspects of the embodiments can be better understood with references to the following drawings. The components in the drawings are not necessarily drawn to scale, the emphasis instead being located upon clearly illustrating the principles of the embodiments. Moreover, in the drawings, like reference numerals designate corresponding parts throughout the several views.

FIG. 1 is an exploded view of an enclosure assembly according to one embodiment.

FIG. 2 is similar to FIG. 1, but viewed from a different aspect.

FIG. 3 is an assembled view of the enclosure assembly of FIG. 1, but the enclosure assembly is assembled in a longitudinal direction.

FIG. 4 is an assembled view of the enclosure assembly of FIG. 1, but the enclosure assembly is assembled in a horizontal direction.

FIG. 5 is an exploded view of an enclosure assembly according to another embodiment.

FIG. 6 is similar to FIG. 5, but viewed from a different aspect.

FIG. 7 is an assembled view of the enclosure assembly of FIG. 5.

FIG. 8 is a cross-sectional view taken along a line VIII-VIII of the enclosure assembly of FIG. 7.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

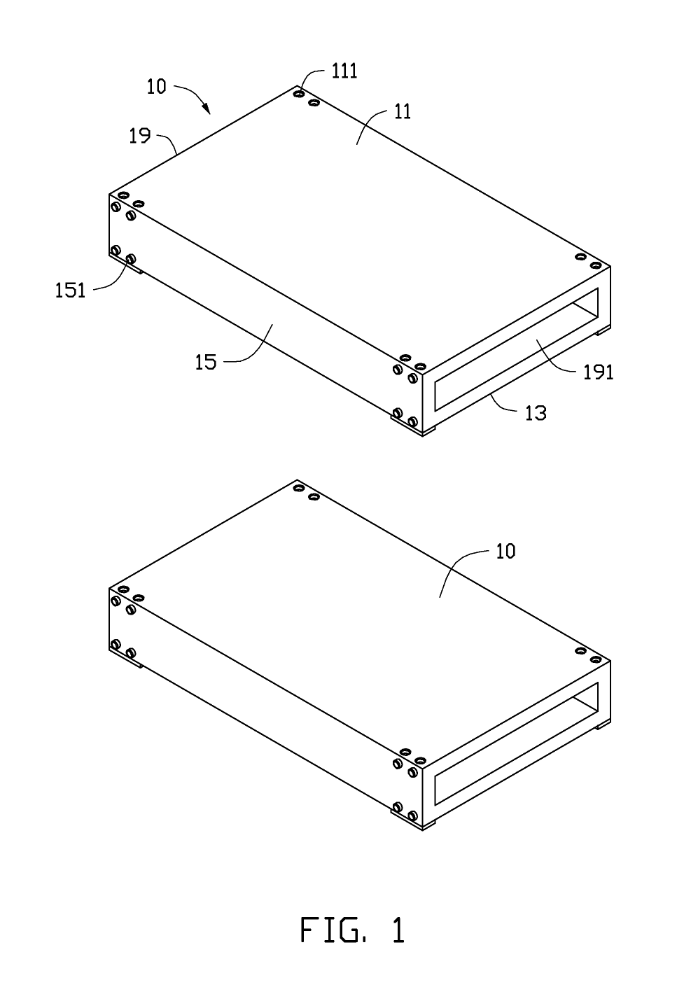

FIG. 1 is an enclosure assembly in accordance with one embodiment. The enclosure assembly includes a plurality of trays 10 (only two shown). Each of the plurality of trays 10 can receive a data storage (not shown), such as a hard disk driver or a floppy disk driver, for example.

Each of the trays 10 includes a top wall 11, a bottom wall 13, a first sidewall 15, a second sidewall 17, and a rear wall 19. The top wall 11 and the bottom wall 13 are parallel to each other. The first sidewall 15 and the second sidewall 17 are parallel to each other and perpendicularly connected to the top wall 11 and the bottom wall 13.

The rear wall 19 is substantially perpendicularly connected to the top wall 11, the bottom wall 13, the first sidewall 15 and the second sidewall 17. The top wall 11, the bottom wall 13, the first sidewall 15 and the second sidewall 17 cooperatively define an accommodating space 191.

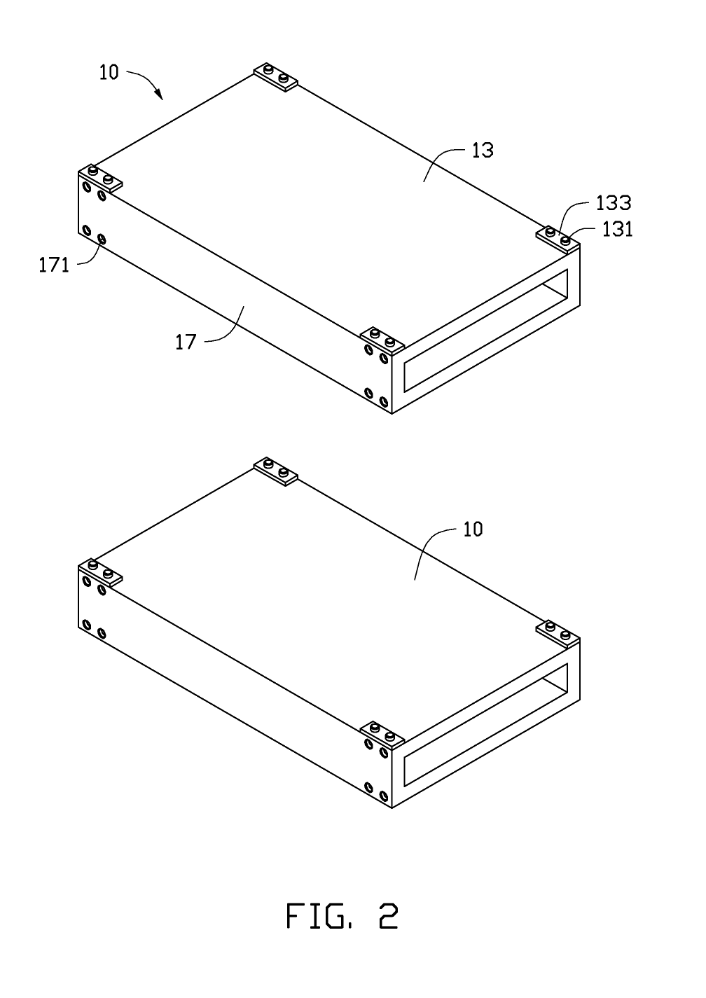

FIGS. 1 and 2 show that in one embodiment, the top wall 11 defines a plurality of securing holes 111. A plurality of positioning posts 131 protrudes from the bottom wall 13, corresponding to the plurality of securing holes 111. A plurality of washers 133 is located on the bottom wall 13, and each of plurality of washers 133 surrounds each of the plurality of positioning posts 131. The drawings show that each corner of the top wall 11 has two securing holes 111, and each corner of the bottom wall 13 has two positioning posts 131 corresponding to the two securing holes 111. Each of the plurality of washers 133 is made of plastic. A plurality of engaging posts 151 protrudes from the first sidewall 15, and the second sidewall 17 defines a plurality of engaging holes 171 corresponding to the plurality of engaging posts 151. The FIG. 2. shows that, each of corners of the first sidewall 15 has two engaging posts 151, and each of corners of the second sidewall 17 has two engaging holes 171.

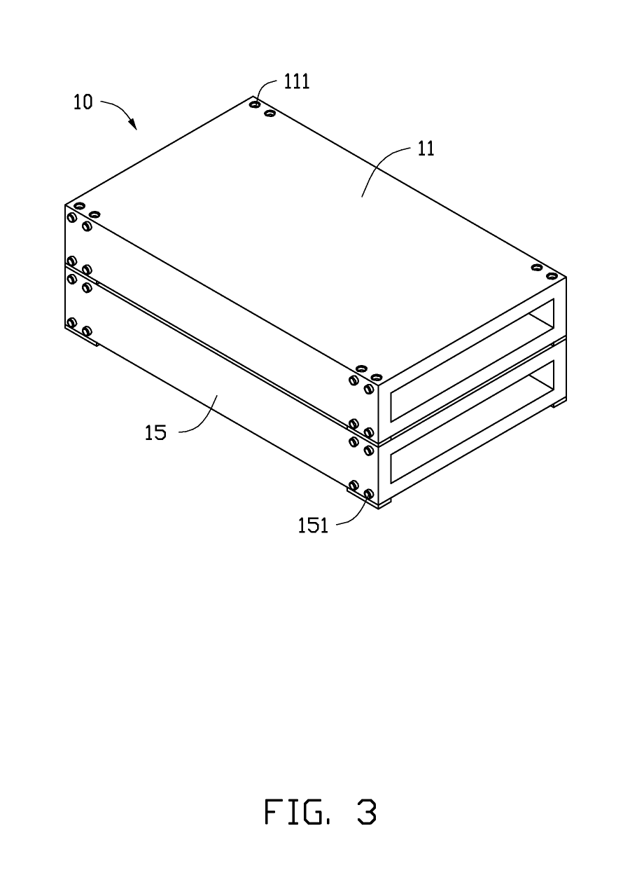

FIG. 3 shows that in assembly of the plurality of trays 10 in a longitudinal direction, each of the plurality of positioning posts 131 of the above tray 10 is engaged into each of the corresponding plurality of securing holes 111 of the below tray 10 to secure two adjacent trays 10 together in the longitudinal direction. The plurality of washers 133 in the above tray 10 abuts the top wall 11 in the below tray 10, to absorb shake. When detachment of the plurality of trays 10, is needed, a pull force is applied to two adjacent trays 10 in the longitudinal direction, until each of the plurality of positioning posts 131 is disengaged from each of the plurality of securing holes 111.

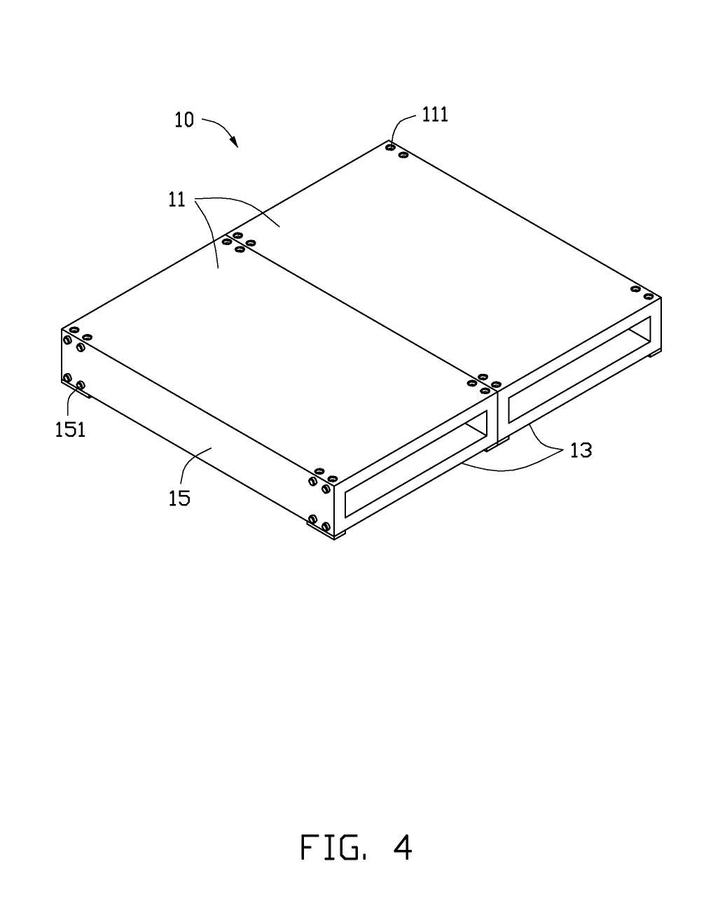

FIGS. 4 shows that in one embodiment, in assembly of the plurality of trays 10 in a horizontal direction, the plurality of trays 10 are placed in the horizontal direction. Each of the plurality of engaging posts 151 of the right tray 10 is engaged into each of the corresponding plurality of engaging holes 171 of the left tray 10 to secure two adjacent trays 10 together in the horizontal direction. When detachment of the plurality of trays 10, is needed, a pull force is applied to two adjacent trays 10 in the horizontal direction, until each of the plurality of engaging posts 151 is disengaged from each of the plurality of engaging holes 171.

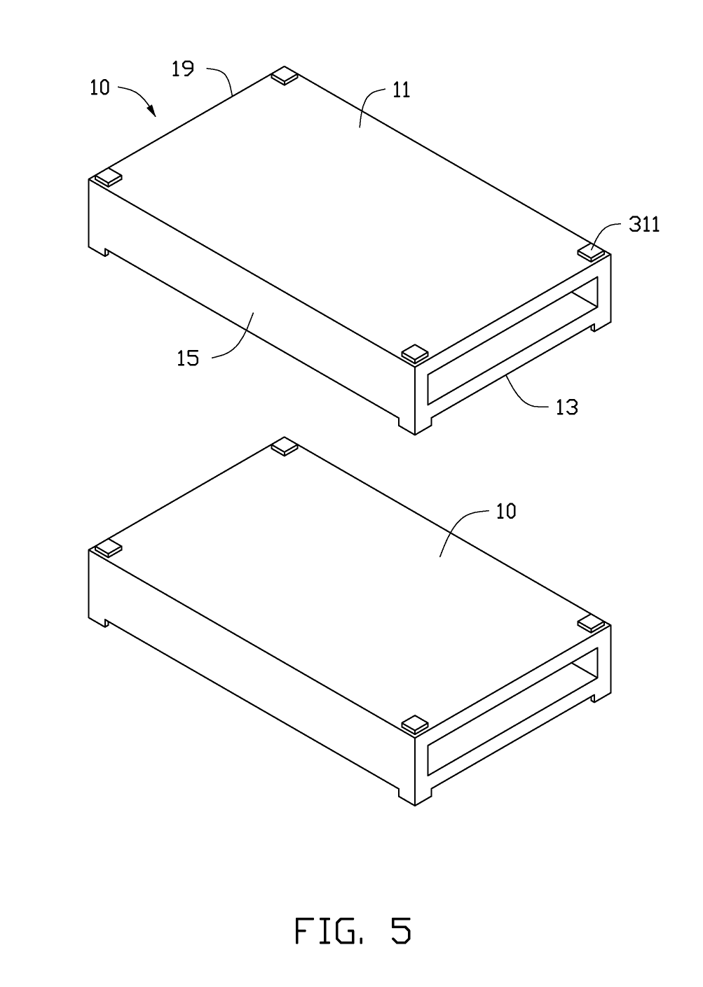

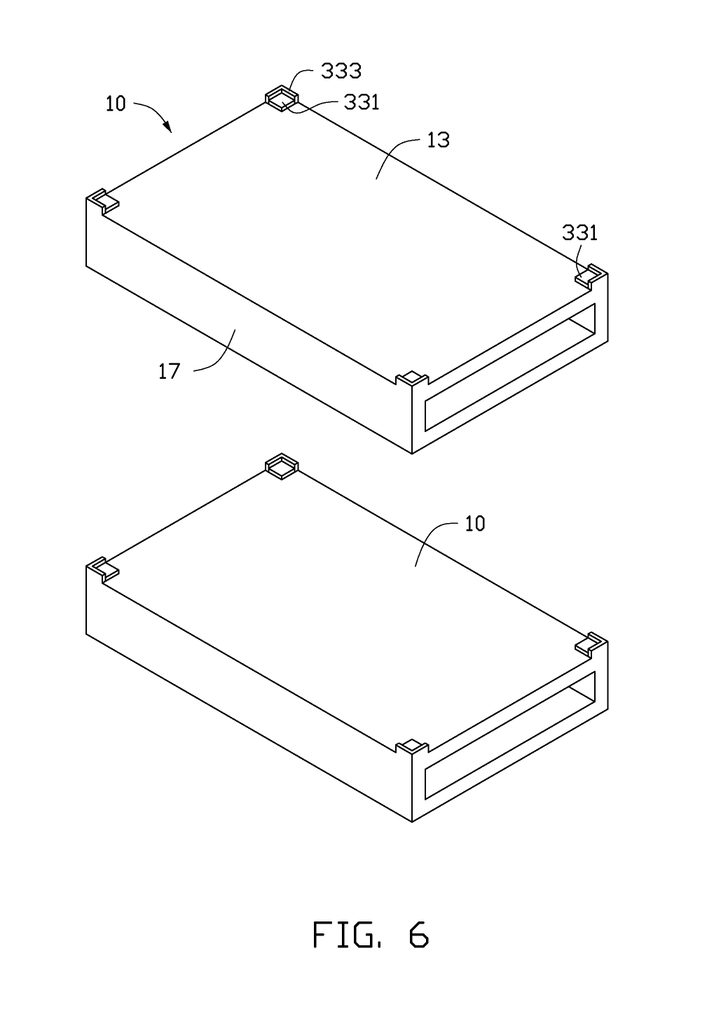

FIGS. 5 and 6 shows that, in other embodiments, a plurality of first absorbing blocks 311 is located on the top wall 11. A plurality of second absorbing blocks 331 is located on the bottom wall 13, corresponding to the plurality of first absorbing blocks 311. A plurality of blocking structures 333 is located on the bottom wall 13, surrounding adjacent edges of plurality of second absorbing blocks 331. In FIG. 2 shows that, each of corners of the top wall 11 has one first absorption block 311. Each of corners of the bottom wall 13 has one second absorption block 331 and one blocking structure 333. The plurality of first absorption blocks 311 and the plurality of second absorption blocks 331 are magnets and attached to the top wall 11, the bottom wall 13 via adhesion or welding, for example. Each of the plurality of blocking structures 333 is substantially L-shaped. The height of each blocking structure 333 is substantially equal to the thickness of each first absorption block 311 plus the thickness of the second absorption block 331. Each of plurality of first absorption blocks 311 in one of the plurality of trays 10 is in a line with each of the plurality of second absorption blocks 331 in another one of the plurality of trays 10, and the line is substantially perpendicular to the top wall 11.

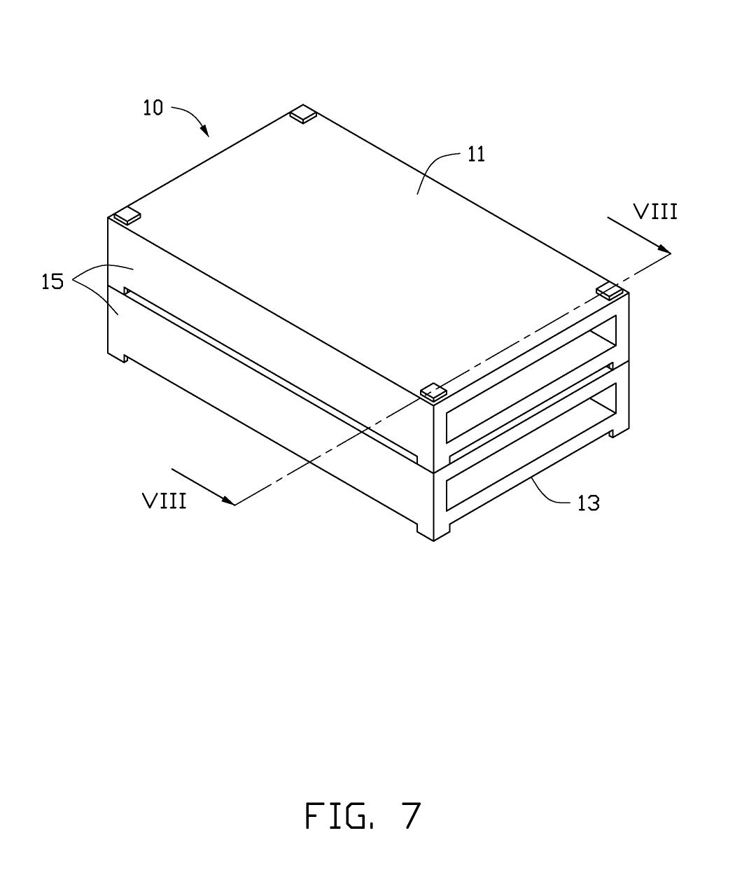

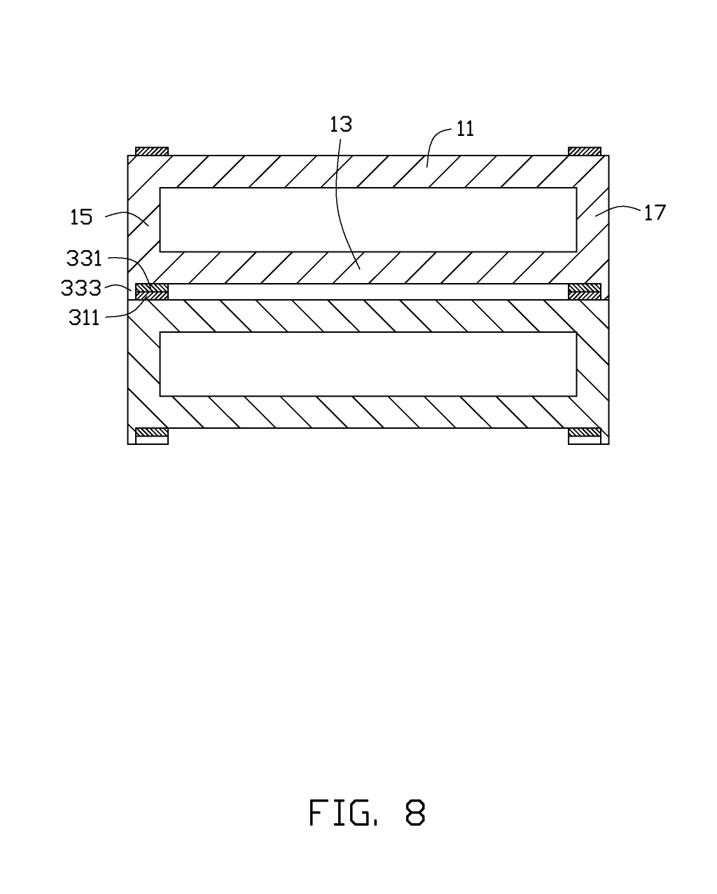

FIGS. 7 and 8 show that in assembly of the plurality of trays 10, the plurality of trays 10 are placed in a longitudinal direction. Each of the plurality of second absorbing blocks 331 of the above tray 10 is drawn to each of the plurality of first absorbing blocks 311 of the below tray 10, to prevent two adjacent trays 10 from moving relative to each other in a first direction perpendicular to the top wall 11. Each of the plurality of blocking structures 333 of the above tray 10 is engaged with adjacent edges of each of the plurality of first absorption block 311, to prevent the two adjacent trays 10 from moving relative to each other in a plane that substantially parallel to the top wall 11. The plurality of trays 10 are thereby mounted together easily.

In disassembly of the plurality of trays 10, two adjacent of the plurality of trays 10 are pulled away from each other, until the force is greater than a magnetic force between each of the plurality of first absorbing blocks 311 and each of the plurality of second absorbing blocks 331. The two adjacent of the plurality of trays 10 can be detached easily.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

1. An enclosure assembly comprising:
a plurality of trays, each of the plurality of trays comprising a first sidewall and a second sidewall opposite to the first sidewall, a plurality of engaging posts are located on the first sidewall, and a plurality of engaging holes are defined in the second sidewall; and each of the four engaging posts in one of the plurality of trays is engaged in each of the plurality of engaging holes in another one of the plurality of trays, to secure two adjacent of the plurality of trays in a horizontal direction.

2. The enclosure assembly of claim 1, wherein each of the plurality of trays comprises a top wall and a bottom wall, opposite to the top wall; the top wall defines a plurality of securing holes; and a plurality of positioning posts is located on the bottom wall, and each of the plurality of positioning posts in the one of the plurality of trays is engaged in each of plurality of securing holes in another one of the plurality of trays, to secure the two adjacent of the plurality of trays in a longitudinal direction.

3. The enclosure assembly of claim 2, wherein a plurality of washers is located on the bottom wall, each of the washers surrounds each of the plurality of positioning posts in the one of the plurality of trays and abuts the top wall of the another one of plurality of trays.

4. The enclosure assembly of claim 3, wherein each of the plurality of washers is made of plastic.

5. The enclosure assembly of claim 1, wherein each of the plurality of trays comprises a top wall and a bottom wall opposite to the top wall; a plurality of first absorbing blocks is located on the top wall; a plurality of second absorbing blocks is located on the bottom wall; and each of the plurality of second absorbing blocks in the one of the plurality of trays is drawn to each of the plurality of first absorbing blocks in another one of the plurality of trays, to prevent the two adjacent of the plurality of trays from moving along a first direction that perpendicular to the top wall.

6. The enclosure assembly of claim 5, wherein a plurality of blocking structures are located on the bottom wall; and each of the plurality of blocking structures surrounds each of the plurality of the second absorbing blocks in the one of the plurality of trays and is engaged with each of the plurality of first absorbing blocks in another one of the plurality of trays, to prevent the two adjacent of the plurality of trays from moving in a plane that parallel to the top wall.

7. The enclosure assembly of claim 6, wherein the height of each of the plurality of blocking structures is equal to a thickness of each of first absorbing blocks plus a thickness of each of the second absorbing blocks.

8. The enclosure assembly of claim 6, wherein each of plurality of blocking structures is substantially L-shaped.

9. The enclosure assembly of claim 5, wherein each of the second absorbing blocks, in the one of the plurality of trays, is in a line with each of the first absorbing blocks of the another one of the plurality of trays, and the line is substantially perpendicular to the top wall.

10. The enclosure assembly of claim 5, wherein the plurality of first absorbing blocks and the plurality of second absorbing blocks are magnets.

11. An enclosure assembly comprising:
a plurality of trays, each of the plurality of trays comprising a first sidewall and a second sidewall opposite to the first sidewall, four pairs of two engaging posts are located on the first sidewall, and four pairs of two engaging holes are defined in the second sidewall; and each of the four pairs of two engaging post is engaged in each of the four pairs of two engaging holes, to prevent two adjacent of the plurality of trays from moving relative to each other.

12. The enclosure assembly of claim 11, wherein each of the plurality of trays comprises a top wall and a bottom wall opposite to the top wall, the top wall defines four pairs of two securing holes, four pairs of two positioning posts are located on the bottom wall, and each of the four pairs of two positioning post in the one of the plurality of trays is engaged in each of the four pairs of two securing holes in another one of the plurality of trays, to prevent the two adjacent of the plurality of trays from moving relative to each other.

13. The enclosure assembly of claim 12, wherein four washers is located on the bottom wall, each of the four washer surrounds each the four pairs of two positioning posts in the one of the plurality of trays and abuts the top wall of the another one of plurality of trays.

14. The enclosure assembly of claim 13, wherein each of the four washers is made of plastic.

15. The enclosure assembly of claim 11, wherein each of the plurality of trays comprises a top wall and a bottom wall opposite to the top wall, a plurality of first absorbing blocks is located on the top wall, a plurality of second absorbing blocks is located on the bottom wall, and each of the plurality of second absorbing blocks in the one of the plurality of trays is drawn to each of the plurality of first absorbing blocks in another one of the plurality of trays, to prevent the two adjacent of the plurality of trays from moving along a first direction that perpendicular to the top wall.

16. The enclosure assembly of claim 15, wherein a plurality of blocking structures are located on the bottom wall, each of the plurality of blocking structures surrounds each of the plurality of the second absorbing blocks in the one of the plurality of trays and is engaged with each of the plurality of first absorbing blocks in another one of the plurality of trays, to prevent the two adjacent of the plurality of trays from moving in a plane that parallel to the top wall.

17. The enclosure assembly of claim 16, wherein the height of each of the plurality of blocking structures is equal to a thickness of each of first absorbing blocks plus a thickness of each of the second absorbing blocks.

18. The enclosure assembly of claim 16, wherein each of plurality of blocking structures is substantially L-shaped.

19. The enclosure assembly of claim 15, wherein each of the second absorbing blocks in the one of the plurality of trays is in a line with each of the first absorbing blocks of the another one of the plurality of trays, and the line is substantially perpendicular to the top wall.

20. The enclosure assembly of claim 15, wherein the plurality of first absorbing blocks and the plurality of second absorbing blocks are magnets.
